(19) United States
(12) Patent Application Publication
(10) Pub. No.: US 2018/0287519 A1
(43) Pub. Date: Oct. 4, 2018

(54) MOTOR DRIVE DEVICE

(71) Applicant: FANUC CORPORATION, Yamanashi (JP)

(72) Inventor: Hitoshi ISHIDA, Yamanashi (JP)

(21) Appl. No.: 15/925,478

(22) Filed: Mar. 19, 2018

(30) Foreign Application Priority Data
Apr. 3, 2017 (JP) 2017-073567

(51) Int. Cl. H02P 3/12; H02P 15/00; G01R 19/15; G01R 19/165

(52) U.S. Cl. CPC H02P 3/12; G01R 19/165; G01R 19/15; H02P 15/00

(57) ABSTRACT

Provided is a motor drive device including: a current detector that detects a current flowing through a power line supplying power to a brake-equipped motor; and a controller that controls the brake-equipped motor based on the current value detected by the current detector. The controller includes a determination part that determines, when actuating the brake-equipped motor whose brake is in a braking state, states of the power line and the brake-equipped motor, based on the current value detected by the current detector after applying a voltage between the power lines. The controller outputs a release instruction signal for releasing the brake when the determination part determines that the states are normal.

### CROSS-REFERENCE TO RELATED APPLICATIONS

This application claims the benefit of and priority to Japanese Patent Application No. 2017-073567, filed on Apr. 3, 2017, the entire content of which is incorporated herein by reference.

### FIELD OF THE INVENTION

The present invention relates to a motor drive device.

### BACKGROUND OF THE INVENTION

Conventionally, when starting control of a motor arranged outside a motor drive device, a brake has been released by issuing an instruction from the motor drive device and actuating a brake circuit (see Japanese Unexamined Patent Application, Publication No. 2013-226619, for example).

### SUMMARY OF THE INVENTION

An aspect of the present invention provides a motor drive device including: a current detector that detects a current value flowing through a power line supplying power to a brake-equipped motor; and a controller that controls the brake-equipped motor based on the current value detected by the current detector. The controller includes a determination part that determines, when actuating the brake-equipped motor whose brake is in a braking state, states of the power line and the brake-equipped motor, based on the current value detected by the current detector after applying a voltage between the power lines. The controller outputs a release instruction signal for releasing the brake when the determination part determines that the states are normal.

### BRIEF DESCRIPTION OF THE DRAWINGS

FIG. 1 is a block diagram illustrating a motor drive device of an embodiment of the present invention.

FIG. 2 is a diagram illustrating a waveform example of a voltage applied between power lines, before actuation of a brake-equipped motor by the motor drive device of FIG. 1.

FIG. 3 is a diagram illustrating a case where a current flowing through a power line is within a normal current value range, after application of the pulsating voltage of FIG. 2.

FIG. 4 is a diagram illustrating a case where a current flowing through a power line is not within the normal current value range, after application of the pulsating voltage of FIG. 2.

FIG. 5 is a diagram illustrating another example of a case where a current flowing through a power line is not within the normal current value range, after application of the pulsating voltage of FIG. 2.

FIG. 6 is a block diagram illustrating a modification of the motor drive device of FIG. 1.

### DESCRIPTION OF EMBODIMENT(S) OF THE INVENTION

A motor drive device 1 of an embodiment of the present invention will be described below with reference to the drawings.

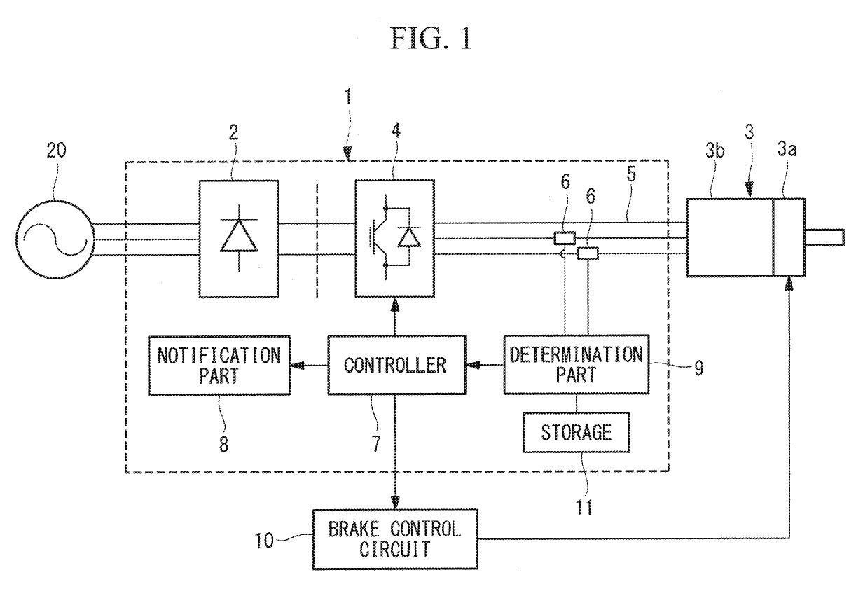

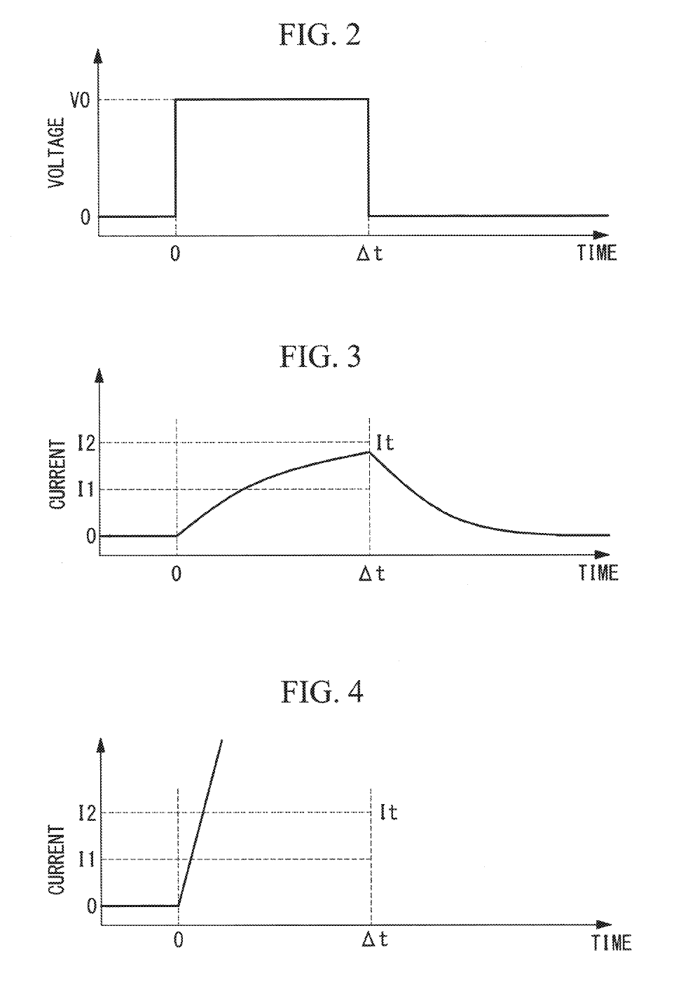

As illustrated in FIG. 1, the motor drive device 1 of the embodiment includes a converter 2 that converts an AC voltage from a power source 20 to a DC voltage, and an inverter 4 that converts the DC voltage output from the converter 2 to a three-phase AC voltage and outputs the three-phase AC voltage to a brake-equipped motor 3.

The motor drive device 1 also includes current sensors (current detectors) 6 that detect currents flowing through power lines 5 supplying power to the brake-equipped motor 3 from the inverter 4, a controller 7 that controls the inverter 4 based on current values detected by the current sensors 6, and a notification part 8.

Moreover, the motor drive device 1 includes a determination part 9 that determines states of the power line 5 and the brake-equipped motor 3, based on the current values detected by the current sensor 6. The controller 7 is configured to decide whether to output a release instruction signal for releasing a brake 3a of the brake-equipped motor 3, according to the determination result of the determination part 9.

The determination part 9 and the controller 7 are configured of a processor and a memory.

The notification part 8 is configured to receive an instruction from the controller 7 and send a notification of the instruction, when the determination part 9 determines that the brake-equipped motor 3 or the power line 5 is not in a normal state.

The release instruction signal from the controller 7 is input into a brake control circuit (controller, control circuit) 10. The brake control circuit 10 is configured to switch the brake 3a of the brake-equipped motor 3 between a braking state and a released state, depending on presence or absence of the release instruction signal.

The current sensor 6 is provided in at least two of the three power lines 5, which supply power consisting of three-phase AC to a motor 3b of the brake-equipped motor 3. Hence, the current sensors 6 can detect currents corresponding to all three phases of the three-phase AC.

When actuating the brake-equipped motor 3, the controller 7 actuates the inverter 4 such that a pulsating voltage V0 having a predetermined time width Δt is applied between the power lines 5 of the phases, before releasing the brake 3a.

The determination part 9 has a storage (memory) 11 that pre-stores a range (normal current value range) I1 to I2 of a current value flowing through the power line 5 after passage of the time Δt from the start of application of voltage, when the aforementioned predetermined pulsating voltage V0 is applied while the power line 5 in a normal state is normally connected to the brake-equipped motor 3 in a normal state.

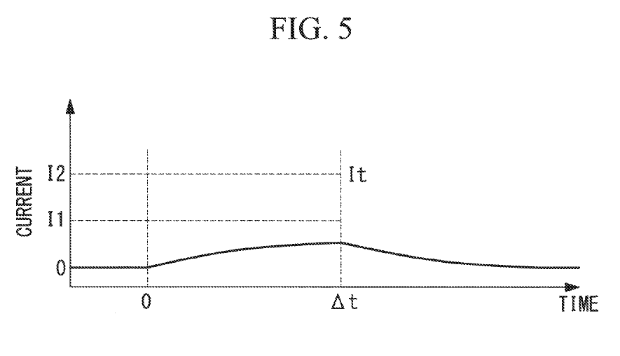

The determination part 9 determines whether the current values detected by all current sensors 6 are within the range of current values stored in the storage 11. If the current values are within the range as illustrated in FIG. 3, the determination part 9 outputs a determination result indicating “Normal” to the controller 7, and if the current values are not within the range as illustrated in FIG. 4 or 5, the determination part 9 outputs a determination result indicating “Abnormal” to the controller 7.

Upon receipt of a determination result indicating “Normal” from the determination part 9, the controller 7 outputs a release instruction signal for releasing the brake 3a to the brake control circuit 10. On the other hand, upon receipt of a determination result indicating “Abnormal” from the determination part 9, the controller 7 does not output any release instruction signals to the brake control circuit 10, but instead makes the notification part 8 send a notification that the determination result indicating “Abnormal” has been made.

An operation of the motor drive device 1 of the embodiment configured in this manner will be described below.

In order to drive the brake-equipped motor 3 by use of the motor drive device 1 of the embodiment, before driving the brake-equipped motor 3 whose brake 3a is in a braking state, the controller 7 applies a predetermined pulsating voltage between the power lines 5, and the current sensor 6 detects the current value flowing through the power line 5.

The determination part 9 compares the current value detected by the current sensor 6 with the normal current value range stored in the storage 11. If the current value is out of the normal current value range, it is determined “Abnormal,” and the controller 7 makes the notification part 8 send a notification indicating that the state is “Abnormal,” without outputting any release instruction signals to the brake control circuit 10.

Thus, it is possible to advantageously prevent releasing of the brake 3a while there is some trouble in the power line 5, the brake-equipped motor 3, the current sensor 6, or the inverter 4. In particular, in a case where the brake-equipped motor 3 is placed in a gravity shaft of a robot or the like, it is possible to advantageously prevent releasing of the brake 3a and dropping of the gravity shaft, when the brake-equipped motor 3 cannot be normally controlled, or when the power line 5 is not connected, for example. Additionally, by sending a notification indicating the abnormal state, it is possible to prompt the worker to check the brake-equipped motor 3 and the power line 5.

On the other hand, if the determination part 9 determines that the current value detected by the current sensor 6 is within the normal current value range stored in the storage 11, the controller 7 outputs a release instruction signal of the brake 3a to the brake control circuit 10. Then, the braking state of the brake 3a of the brake-equipped motor 3 is released, and the brake-equipped motor 3 is operated normally under voltage control by the inverter 4 that follows an instruction signal from the controller 7.

Thus, the motor drive device 1 of the embodiment has an advantage of surely preventing releasing of the brake 3a, when there is a problem in the brake-equipped motor 3, the power line 5, the current sensor 6, or the inverter 4.

Note that although the motor drive device 1 of the embodiment is configured such that the determination part 9 determines the normal and abnormal states according to whether the current values are within the normal current value range, the invention is not limited to this. Instead, troubles may be classified according to the magnitude of the current value, and the notification part 8 may send a notification indicating information on the state of the power line 5 or the brake-equipped motor 3.

For example, as illustrated in FIG. 4, when the current value detected by the current sensor 6 exceeds the normal current value range, it is conceivable that a short or an insulation deterioration has occurred in a motor winding. Also, as illustrated in FIG. 5, when the current value detected by the current sensor 6 is an excessively small current value that does not reach the normal current value range, it is conceivable that the brake-equipped motor 3 or the power line 5 is deteriorated, or an abnormality such as gain deterioration of the current sensor 6 has occurred. Also, when the current value detected by the current sensor 6 is zero, it is conceivable that the power line 5 is not connected to the motor 3b, an abnormality has occurred in the current sensor 6, or the inverter 4 is not operating normally according to the instruction to the inverter 4.

When the current value detected by the current sensor 6 is out of the normal current value range, it is possible to notify the worker of a more detailed state of the power line 5, the brake-equipped motor 3, the current sensor 6, or the inverter 4, by making the notification part 8 send a notification indicating one of the pieces of information mentioned above.

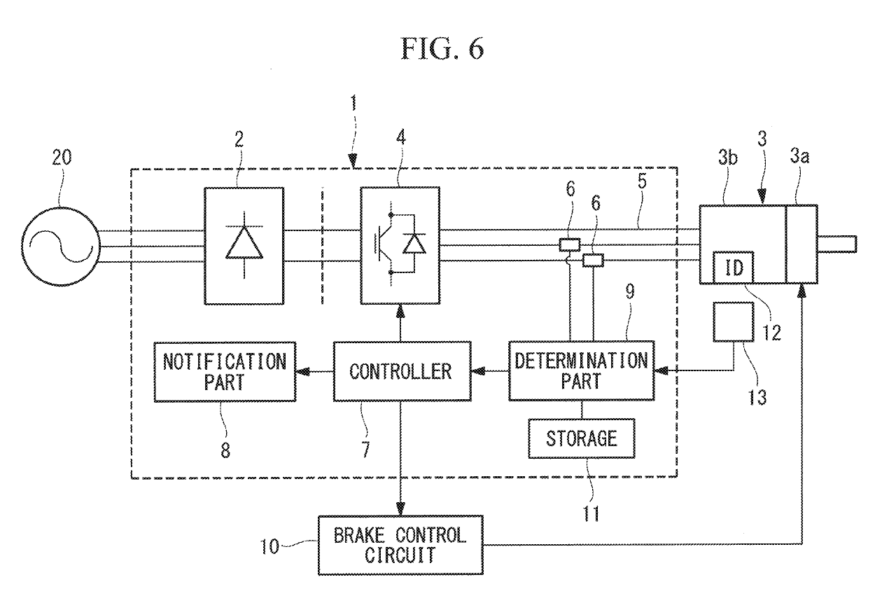

Additionally, since the normal current value range varies by individual differences of the brake-equipped motor 3, as illustrated in FIG. 6, the brake-equipped motor 3 may include an ID storage 12 that stores identification information. A reader (identification information input part) 13 that reads the identification information in the ID storage 12 may be provided, and a normal current value range associated with the identification information may be stored in the storage 11. When the brake-equipped motor 3 is replaced, it is possible to determine the normal or abnormal state regardless of the individual difference, by reading the identification information in the ID storage 12 by the reader 13, and reading an associated normal current value range from the storage 11 by the determination part 9 and making a determination therewith. Instead of providing the reader 13, identification information may be input manually.

Additionally, although a range of current values measured in advance in a normal state is stored as a normal current value range, a normal current value range may be obtained by calculating a time constant from the voltage value of DC voltage output from the converter 2, and an inductance and resistance of the brake-equipped motor 3.

This is advantageous in that a more accurate normal current value range can be set, so that presence or absence of a problem can be determined more accurately.

From the above-described embodiment, the following invention is derived.

An aspect of the present invention provides a motor drive device including: a current detector that detects a current value flowing through a power line supplying power to a brake-equipped motor; and a controller that controls the brake-equipped motor based on the current value detected by the current detector. The controller includes a determination part that determines, when actuating the brake-equipped motor whose brake is in a braking state, states of the power line and the brake-equipped motor, based on the current value detected by the current detector after applying a voltage between the power lines. The controller outputs a release instruction signal for releasing the brake when the determination part determines that the states are normal.

According to this aspect, the determination part determines, when actuating the brake-equipped motor whose brake is in a braking state, states of the power line and the brake-equipped motor, based on the current value detected by the current detector after applying a voltage between the power lines. When it is not determined that the power line and the brake-equipped motor are in a normal state, the controller does not output an instruction signal for releasing the brake, and therefore the brake is maintained. Hence, it is possible to prevent releasing of the brake when there is a problem in the motor or the power line.

In the above aspect, a storage that stores a normal current value range which is a range of current values when a predetermined voltage is applied between the power lines while the states are normal may be provided. Here, the determination part may determine the states by comparing the current value detected by the current detector and the normal current value range stored in the storage.

With this, when actuating the brake-equipped motor whose brake is in a braking state, the determination part compares the current value detected by the current detector after the controller applies a predetermined voltage between the power lines, and the normal current value range stored in the storage. If the detected current value is within the normal current value range, it is determined that the power line and the brake-equipped motor are in a normal state and the brake is released.

In the above aspect, a notification part that sends a notification of the states determined by the determination part may be provided.

With this, when actuating the brake-equipped motor in a braking state, the worker can be notified by the notification part of the reason why the brake is not released.

In the above aspect, the storage may store information on the states in association with a range of current values when a predetermined voltage is applied between the power lines, and the notification part may send a notification of the information on the states.

With this, states of the power line and the brake-equipped motor are classified depending on the current value range when a predetermined voltage is applied between the power lines, and by sending a notification of the classified information, the worker can more specifically recognize the states of the power line and the brake-equipped motor.

In the above aspect, an identification information input part to which identification information on the brake-equipped motor is input may be provided. The storage may store the normal current value range in association with the identification information on the brake-equipped motor, and the determination part may determine the states by use of the normal current value range stored in the storage in association with the identification information input in the identification information input part.

With this, even when the brake-equipped motor is changed, by inputting the identification information on the changed brake-equipped motor, it is possible to determine the states of the power line and the brake-equipped motor by use of the normal current value range according to the type of the brake-equipped motor.

In the above aspect, the controller may include a control circuit that controls the brake of the brake-equipped motor.

1. A motor drive device comprising:
a current detector that detects a current value flowing through a power line supplying power to a brake-equipped motor; and
a controller that controls the brake-equipped motor based on the current value detected by the current detector, wherein
the controller includes a determination part that determines, when actuating the brake-equipped motor whose brake is in a braking state, states of the power line and the brake-equipped motor, based on the current value detected by the current detector after applying a voltage between the power lines, and the controller outputs a release instruction signal for releasing the brake when the determination part determines that the states are normal.

2. The motor drive device according to claim 1 further comprising a storage that stores a normal current value range which is a range of current values when a predetermined voltage is applied between the power lines while the states are normal, wherein
the determination part determines the states by comparing the current value detected by the current detector and the normal current value range stored in the storage.

3. The motor drive device according to claim 2 further comprising a notification part that sends a notification of the states determined by the determination part.

4. The motor drive device according to claim 3, wherein:
the storage stores information on the states in association with a range of current values when a predetermined voltage is applied between the power lines; and
the notification part sends a notification of the information on the states.

5. The motor drive device according to claim 2 further comprising an identification information input part to which identification information on the brake-equipped motor is input, wherein:
the storage stores the normal current value range in association with the identification information on the brake-equipped motor; and
the determination part determines the states by use of the normal current value range stored in the storage in association with the identification information input in the identification information input part.

6. The motor drive device according to claim 1, wherein
the controller includes a control circuit that controls the brake of the brake-equipped motor.
